(19) United States
(12) Patent Application Publication
(10) Pub. No.: US 2026/0068304 A1
(43) Pub. Date: Mar. 5, 2026

(54) LATCH-UP PREVENTION AND INCREASED DECOUPLING CAPACITOR DENSITY

(71) Applicant: INTERNATIONAL BUSINESS MACHINES CORPORATION, ARMONK, NY (US)

(72) Inventors: Masoud Zabihi, Schenectady, NY (US); Ruilong Xie, Niskayuna, NY (US); Robert Gauthier, Williston, VT (US); Anindya Nath, Watervliet, NY (US); Anthony I-Chih Chou, Guilderland, NY (US)

(21) Appl. No.: 18/818,532

(22) Filed: Aug. 28, 2024

(51) Int. Cl. H01L 27/092; H01L 21/8238; H01L 29/06; H01L 29/417; H01L 29/423; H01L 29/66; H01L 29/775; H01L 29/786

(52) U.S. Cl. CPC H10D 84/854; H10D 30/014; H10D 30/43; H10D 30/6729; H10D 30/6735; H10D 30/6757; H10D 62/121; H10D 84/0186; H10D 84/038

(57) ABSTRACT

A semiconductor device includes a passive device including a passive device including a first backside contact, a shallow trench isolation (STI) above the first backside contact and covering a top surface and an upper half of sidewalls of the first backside contact, and an interconnection layer covering a bottom surface of the first backside contact.

### BACKGROUND

### Technical Field

The present disclosure generally relates to semiconductors, and more particularly, to semiconductors with latch-up prevention and increased decoupling capacitor density structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. Various functionalities, including processing and storage, are increasingly being integrated within a single chip, enabling more compact and efficient systems.

### SUMMARY

According to an embodiment, a semiconductor device includes a passive device including a first backside contact, a shallow trench isolation (STI) above the first backside contact and covering a top surface and an upper half of sidewalls of the first backside contact, a spacer liner covering a lower half of the sidewalls of the first backside contact, and an interconnection layer covering a bottom surface of the first backside contact.

In one embodiment, the passive device includes an interlayer dielectric (ILD) above the STI, a set of P-type doped regions and a set of N-type doped regions on opposite sides of the ILD, and a first N-well region and a second N-well region below the set of P-type doped regions and the set of N-type doped regions. The first N-well region is located on a first side of the spacer liner and the STI, and the second N-well region is located on a second side of the spacer liner and the STI.

In one embodiment, the spacer liner is made of a high-k dielectric material.

In one embodiment, the spacer liner and the STI isolate the first N-well region and the second N-well region from contact with the first backside contact.

In one embodiment, the passive device is electrically connected to a back end of line (BEOL) through a first via.

In one embodiment, the semiconductor device includes an active device including source/drain regions, gate regions, and a second backside contact.

In one embodiment, the active device further comprises alternative layers extended horizontally between two adjacent source/drain regions.

In one embodiment, the active device is electrically connected to a back end of line (BEOL) through a second via.

In one embodiment, the alternative layers include silicon.

According to an embodiment, a method for fabrication of a semiconductor device includes forming a passive device including forming a first backside contact, forming a shallow trench isolation (STI) above the first backside contact and covering a top surface and an upper half of sidewalls of the first backside contact, forming a spacer liner covering a lower half of the sidewalls of the first backside contact, and forming an interconnection layer covering a bottom surface of the first backside contact.

In one embodiment, the method includes forming an interlayer dielectric (ILD) above the STI, forming a set of P-type doped regions and a set of N-type doped regions on opposite sides of the ILD, forming a first N-well region below the set of P-type doped regions and the set of N-type doped regions on a first side of the spacer liner and the STI, and forming a second N-well region below the set of P-type doped regions and the set of N-type doped regions on a second side of the spacer liner and the STI.

In one embodiment, the method includes isolating the first N-well region and the second N-well region from contact with the first backside contact via the spacer liner and the STI.

In one embodiment, the method includes establishing an electrical connection between the passive device and a back end of line (BEOL) through a first via.

In one embodiment, the method includes forming an active device including forming source/drain regions, forming gate regions between the source/drain regions, and forming a second backside contact below one of the source/drain regions.

In one embodiment, the method includes comprising forming alternative layers extended horizontally between two adjacent source/drain regions.

In one embodiment, the method includes establishing an electrical connection between the active device and a back end of line (BEOL) through a second via.

According to an embodiment, a semiconductor device includes a backside contact, a spacer liner covering lower half of sidewalls of the backside contact, and an N-well region connected to spacer liner so that the spacer liner isolates the N-well region from contact with the backside contact. The spacer liner is made of a high-k dielectric material, the N-well region is electrically connected to a voltage source/drain supply, and the backside contact is connected to a voltage drain/source supply or to a ground voltage.

In one embodiment, the semiconductor device includes a shallow trench isolation (STI) above the backside contact and covering a top surface and an upper half of sidewalls of the backside contact, and an interconnection layer covering a bottom surface of the backside contact.

In one embodiment, the semiconductor device includes an interlayer dielectric (ILD) above the STI, a set of P-type doped regions and a set of N-type doped regions on opposite sides of the ILD, and a first N-well region and a second N-well region below the set of P-type doped regions and the set of N-type doped regions. The first N-well region is located on a first side of the spacer liner and the STI, and the second N-well.

In one embodiment, the spacer liner isolates the first N-well region and the second N-well region from contact with the backside contact.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates the latch-up formation, the undershoot and overshoot scenarios in a conventional semiconductor device.

FIG. 1B illustrates a sideview of a latch-up prone region in a conventional semiconductor device.

FIG. 2 illustrates a semiconductor device, in accordance with some embodiments.

FIGS. 3A-3B illustrate a semiconductor device after the formation of the front end of line, middle end of line, and back end of line, in accordance with some embodiments.

FIGS. 4A-4B illustrate a semiconductor device after wafer flip and substrate removal, in accordance with some embodiments.

FIGS. 5A-5B illustrate a semiconductor device after patterning of the backside contact, in accordance with some embodiments.

FIGS. 6A-6B illustrate a semiconductor device after the partial recession of the substrate, in accordance with some embodiments.

FIGS. 7A-7B illustrate a semiconductor device after the removal of the remaining substrate, in accordance with some embodiments.

FIGS. 8A-8B illustrate a semiconductor device after the formation of the bottom interlayer dielectric, in accordance with some embodiments.

FIGS. 9A-9B illustrate a semiconductor device after the formation of the additional bottom interlayer dielectric, in accordance with some embodiments.

FIGS. 10A-10B illustrate a semiconductor device after the backside contact patterning in accordance with some embodiments.

FIGS. 11A-11B illustrate a semiconductor device after the formation of the spacer liner, in accordance with some embodiments.

FIGS. 12A-12B illustrate a semiconductor device after the etching of the shallow trench isolation, in accordance with some embodiments.

FIGS. 13A-13B illustrate a semiconductor device after the formation of the backside contact, in accordance with some embodiments.

FIGS. 14A-14B illustrate a semiconductor device after the formation of the backside interconnect, in accordance with some embodiments.

FIG. 15 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

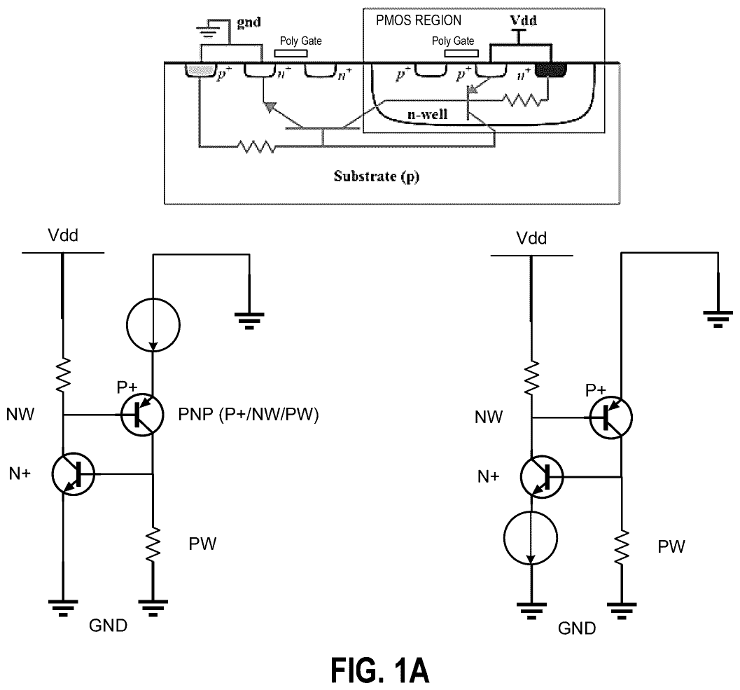

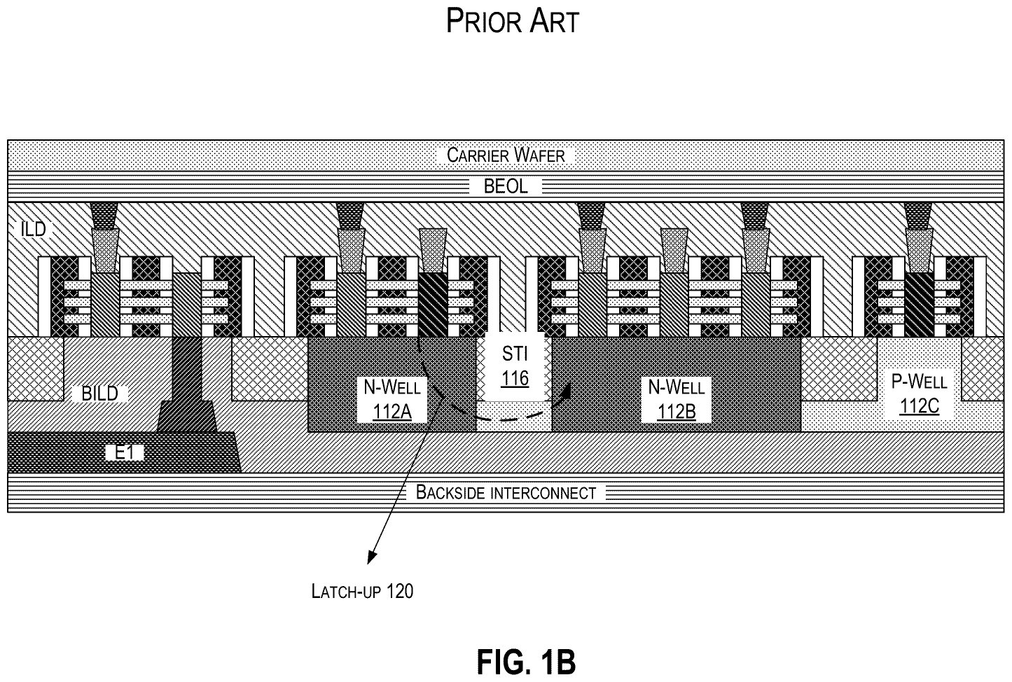

Backside interconnect is recognized as the industry go-to direction for advancing semiconductor technology. By routing interconnections on the backside of the semiconductor wafer, this approach effectively increases the available area for active device components on the frontside, thereby enhancing overall device performance and density. The implementation of backside interconnects allows for more efficient power distribution and signal routing, reducing resistance and inductance associated with longer interconnect paths. Preventing latch-up in integrated circuits is desired due to its potential to cause catastrophic failure. Latch-up refers to the inadvertent creation of a low-impedance path between the power supply rails, typically triggered by certain electrical conditions such as overshoot, undershoot, or transient currents. This low-impedance path can lead to excessive current flow, causing overheating, circuit malfunction, or permanent damage to the integrated circuit. Effective latch-up prevention strategies require careful layout design, proper isolation techniques, and the incorporation of guard rings or substrate ties to mitigate the risk of latch-up occurrences. FIG. 1A illustrates two possible scenarios, e.g., overshoot and undershoot, for occurrence of the parasitic positive-negative-positive-negative (PNPN) silicon-controlled rectifier (SCR) in a conventional complementary metal-oxide semiconductor (CMOS).

In semiconductor devices, overshoot and undershoot are phenomena that can adversely affect signal integrity. Overshot occurs when the voltage of a signal exceeds its intended maximum value during a transition, often due to the inductive and capacitive properties of the interconnects. This excessive voltage can lead to signal distortion, potential damage to the device, and increased electromagnetic interference (EMI). Similarly, undershoot refers to the scenario where the signal voltage drops below its intended minimum value, which can also cause signal integrity issues, increased susceptibility to noise, and potential triggering of unintended states in digital circuits. Both overshoot and undershoot need to be considered in high-speed and high-frequency circuit design, necessitating the use of proper termination techniques, controlled impedance routing, and careful signal integrity analysis to minimize their impact.

The parasitic PNPN SCR structure in complementary metal-oxide-semiconductor (CMOS) technology is a factor in latch-up phenomena. The parasitic SCR is formed inadvertently during the fabrication of CMOS devices, including a PNP transistor and an NPN transistor that are interconnected in such a way that they can form a positive feedback loop. When certain conditions, such as high current injection or excessive voltage, are met, this feedback loop can become self-sustaining, leading to a latch-up condition. Once triggered, the parasitic SCR can conduct a significant amount of current, resulting in elevated temperatures, potential destruction of the device, and failure of the integrated circuit. FIG. 1B illustrates the formation of the parasitic PNPN SCR which causes the latch-up 120. The latch-up 120 can occur between a first N-well region 112A below the P-type doped regions and the N-type doped regions and a second N-well region 112B and via the STI 116 and a P-well region 112C.

In view of the above considerations, disclosed is a semiconductor device to prevent latch-up and increase the decoupling capacitor density. To that end, a spacer liner and shallow trench isolation can over the backside contact to isolate the N-well regions on opposite sides of the backside contact from contact with each other, which minimizes the risk of latch-up. By enabling backside decoupling capacitors, e.g., decaps, and without sacrificing area, the disclosed semiconductor device can enable the inclusion of additional decaps effectively at no cost in terms of space. This approach can create what can be referred to as ‘free’ decaps, since it utilizes otherwise unused areas of the semiconductor device. By implementing decaps in such a manner, it is possible to increase the density of the components within the semiconductor device.

Increasing the density of decaps can further enhance the power integrity of electronic devices. This improvement can be achieved because more decaps provide better regulation and stabilization of the power supply by reducing voltage fluctuations and noise. This is desired for the reliable operation of high-performance electronic systems where even minor power issues can affect the functionality and efficiency of the device. Thus, this strategy not only optimizes the use of available space but also contributes directly to the enhanced performance and reliability of electronic systems.

Accordingly, the teachings herein provide methods and systems of semiconductor device formation with the spacer liner over the backside contact to isolate the doped regions surrounding the backside contact from direct contact. The techniques described herein may be implemented in a number of ways. Example implementations are provided below with reference to the following figures.

Example Semiconductor Device with Spacer Liner Over the Backside Contact Structure

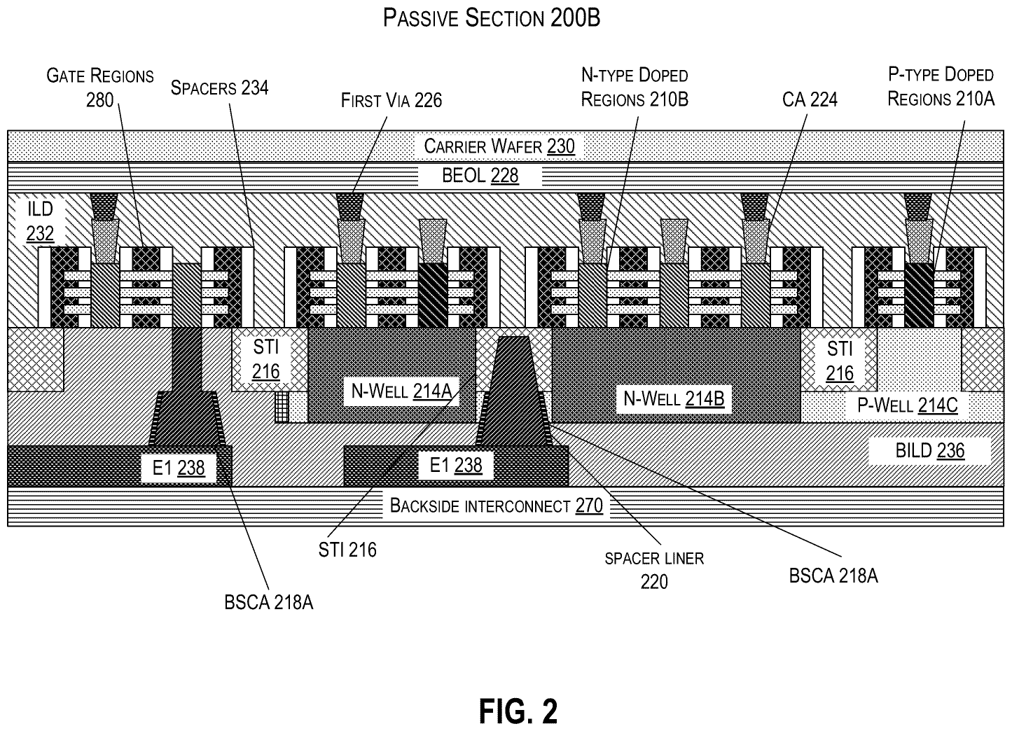

Reference now is made to FIG. 2, which is a simplified cross-section view of a semiconductor device, consistent with an illustrative embodiment. In various embodiments, the semiconductor device includes an active section and a latch-up prone section.

The semiconductor device includes a set of P-type doped regions 210A, a set of N-type doped regions 210B, a first N-well region 214A, a second N-well region 214B, a P-well region 214C, a shallow trench isolation, STI 216 over a first backside contact and covering a top surface and an upper half of the sidewalls of the backside contact, a first backside contact, BSCA 218A, a spacer liner 220 over the lower half of the sidewalls of the BSCA 218A, frontside contacts, CA 224, a first via 226, a back end of line, BEOL 228, a carrier wafer 230, an interlayer dielectric, ILD 232, spacers 234, a bottom ILD, BILD 236, a metal layer, E1 238, a backside interconnect 270, and gate regions 280.

Each pair of the set of N-type doped regions 210B and the set of P-type doped regions 210A can be created by doping two regions, one with a type P dopant, which introduces an excess of positive charge carriers (holes), and the other with a type N dopant, which introduces an excess of negative charge carriers (electrons). Similarly, the first N-well region 214A, the second N-well region, and the P-well region 214C can be doped with N-type and P-type dopants, respectively.

An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current. In some embodiments, the first N-well region 214A and the second N-well region 214B can form on the first side and second side of the spacer liner 220 and the STI 216, respectively, which can facilitate the control of threshold voltages and channel formation in the semiconductor device.

The STI 216 can electrically isolate different components by filling the trenches with an insulating material, such as silicon dioxide. The STI 216 can prevent electrical interference and crosstalk between adjacent devices, ensuring that each component operates independently without affecting its neighbors.

In some embodiments, by placing the STI 216 between the BSCA 218A and either of the first N-well region 214A or the second N-well region 214B, a backside decoupling capacitor can be formed. The STI 216, which can be composed of silicon dioxide, acts as the dielectric material separating the BSCA 218A, which is made of a metallic compound, and the first N-well region 214A or the second N-well region 214B of the capacitor. Such a configuration can enhance the capacitor's performance by utilizing the insulating properties of the STI 216 to prevent direct electrical flow while allowing an electric field to develop across it, storing electrical energy temporarily.

The BSCA 218A can serve as one electrode of the capacitor, accumulating positive charge, while the N-well region, enriched with electrons, holds an equivalent negative charge. This setup is desired for the capacitor's function, particularly in stabilizing voltage levels and filtering out noise by providing a local charge reservoir. Positioned on the backside of the semiconductor device, the capacitor can facilitate smoothing voltage fluctuations that occur as active components draw transient currents, which in turn helps in maintaining power integrity for devices for which stable voltage levels are vital for reliable operation. In some embodiments, the sidewalls of the STI 216 can be thinned to increase the capacitance of the capacitor.

The spacer liner 220, can be made of a high-k dielectric material. High-k materials can be used because of their dielectric constant, which provides enhanced capacitance and leakage performance in the semiconductor devices. The spacer liner 220, along with the STI 216, can isolate the first N-well region 214A and the second N-well region 214B from direct contact with the BSCA 218A. Such an isolation can enable preventing unwanted electrical interactions that could compromise the device's performance. Similar to the STI 216, by placing the spacer liner 220 between the BSCA 218A and either of the first N-well region 214A or the second N-well region 214B, a backside decoupling capacitor can be formed. The spacer liner 220 acts as the dielectric material separating the BSCA 218A and the first N-well region 214A or the second N-well region 214B of the capacitor. Such a configuration can enhance the capacitor's performance by utilizing the insulating properties of the spacer liner 220 to prevent direct electrical flow while allowing an electric field to develop across it, storing electrical energy temporarily.

As mentioned earlier, latch-up can arise within peripheral or internal circuits, either within a single circuit (intra-circuit) or between multiple circuits (inter-circuit). For example, latch-up can occur when a PNPN structure transitions from a low-current high-voltage state to a high-current low-voltage state through a negative resistance region, resulting in an S-Type I-V (current/voltage) characteristic. Latch-up can be particularly initiated by an equivalent circuit including cross-coupled PNP and NPN transistors. With the base and collector regions cross-coupled, current from one device initiates the second device through “regenerative feedback.” These PNP and NPN elements can be diffusions or implanted regions of other circuit elements (such as PFETs, NFETs, and resistors) or actual PNP and NPN bipolar transistors. The PNPN configuration can be formed with a p-diffusion in an n-well and an n-diffusion in a p-substrate, creating a “parasitic PNPN” structure. In such instances, the well and substrate regions are inherently involved in the latch-up current exchange within the device.

Further, latch-up can be triggered by interactions between electrostatic discharge (ESD) devices, input/output (I/O) off-chip drivers, and adjacent circuitry, particularly through substrate initiation from overshoot and undershoot phenomena. Such factors can be generated by CMOS off-chip driver circuitry, receiver networks, and ESD devices. In CMOS I/O circuitry, undershoot and overshoot can lead to substrate injection, where simultaneous switching may result in both noise injection and latch-up conditions. Supporting elements such as pass transistors, resistor elements, test functions, over-voltage dielectric limiting circuitry, bleed resistors, keeper networks, and other components can further contribute to substrate noise injection and latch-up.

As the semiconductor device technology scales down, the reduced p+/n+ spacing lowers the trigger threshold, increasing the susceptibility to CMOS latch-up. The scaling of STI aspect ratios can also heighten CMOS technology's vulnerability to latch-up. Additionally, vertical scaling of wells and lower implant doses for n-wells and p-wells have increased lateral parasitic bipolar current gains, reducing latch-up robustness. The transition from p+ substrates to low-doped p-substrates can diminish latch-up robustness. Although n-wells used as guard ring structures can mitigate latch-up issues, mixed-signal applications and radio frequency chips have increased concerns for noise reduction, leading to further reductions in substrate doping concentration and, consequently, lower latch-up immunity in these technologies. Latch-up can also be triggered by voltage or current pulses on power supply lines. Transient pulses on power rails (such as the substrate or wells) can initiate latch-up processes. Additionally, latch-up can result from stimuli to the well or substrate external to the thyristor structure region by minority carriers.

The CA 224, located over the set of P-type doped regions 210A and the set of N-type doped regions 210B, can establish connections between the set of P-type doped regions 210A and the set of N-type doped regions 210B and the BEOL 228 through the first via 226. The CA 224 can ensure efficient electrical routing and connectivity within the semiconductor device. The fabrication of the CA 224 can involve lithography and etching processes to define the contact area. The CA 224 can be made using conductive materials such as copper (Cu) or tungsten (W).

In some embodiments, the semiconductor device is electrically connected to the BEOL 228 through a first via 226. The BEOL 228 can be the uppermost layer of the integrated circuit and include the interconnects and contact structures for integrating the device into larger circuits. The first via 226 can provide a conductive pathway that facilitates this integration, ensuring that the semiconductor device can effectively interact with other components of the semiconductor assembly.

The semiconductor device can include several structural and functional elements that contribute to its performance and integration within semiconductor technology. The semiconductor device can further include an interlayer dielectric (ILD) situated above the STI 216. The ILD 232 can serve as an insulating layer that separates various conducting layers and components within the semiconductor device. On opposite sides of the ILD 232, the semiconductor device can feature the set of P-type doped region 210A and the set of N-type doped region 210B, which can create p-n junctions and allow for the control of electrical charge flow within the semiconductor device. The arrangement of the set of P-type doped region 210A and the set of N-type doped region 210B on either side of the ILD 232 can facilitate effective separation of charge carriers, enhancing the passive device's electrical performance.

The ILD 232 can be a layer of insulating material to electrically isolate and provide mechanical support between different layers of conducting and active components. The ILD 232 can enable efficient signal transmission, reduce crosstalk, and ensure the proper functioning of the semiconductor device. In an embodiment, the ILD 232 can electrically isolate adjacent conducting layers or active components in the semiconductor device. By providing insulation between different layers, the ILD 232 can prevent electrical shorts, reduce (e.g., minimize) leakage current, and ensure that signals are directed only along the desired pathways. In some embodiments, the ILD 232 can help reduce parasitic capacitance between adjacent metal interconnects or active devices and provide mechanical support to the passive device's structure.

In several embodiments, the BILD 236 can provide structural support to the semiconductor device by maintaining the mechanical integrity and stability of the semiconductor device. The BILD 236 can further help prevent the warping, bending, or cracking of the substrate, particularly during the manufacturing process or subsequent handling. The BILD 236 can ensure that the semiconductor device remains mechanically robust and maintains its dimensional stability.

In an embodiment, the BILD 236 can also serve as a planarization layer in the semiconductor device fabrication process. As various layers are deposited and patterned on the front side of the semiconductor device, irregularities or topographic variations may arise. The BILD 236 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 236 can contribute to improved overall passive device performance. In several embodiments, BILD 236 can facilitate wafer-level testing of the semiconductor device. By providing electrical isolation between the active regions and the backside contact, individual passive device or elements on the semiconductor device can be electrically accessed and tested without interference from neighboring devices or components. This enables efficient and accurate wafer-level testing, ensuring quality control during semiconductor manufacturing.

The backside interconnect 270 can provide backside electrical connection between the semiconductor device and other devices.

In some embodiments, the N-well region, e.g., the first N-well region 214A or the second N-well region 214B, can be connected to VDD (positive supply voltage) and the BSCA 218A to the ground (GND). Such an arrangement leverages the inherent properties of the N-well region and the backside contact to form a capacitor that helps stabilize the voltage supply by smoothing out electrical noise and fluctuations.

In some embodiments, the N-well regions can be directly connected to VDD, which means the N-well region is tied to a higher potential typically used to power the device. Conversely, the BSCA 218A is connected to VSS or ground, establishing a lower potential reference point. This setup forms a basic capacitive structure where the N-well region acts as one plate and the backside contact as the other. This connection scheme can provide a path for charge accumulation and dissipation that aids in the overall stability and performance of the electronic device.

Example Fabrication of Semiconductor Device with Spacer Liner Over Backside Contact

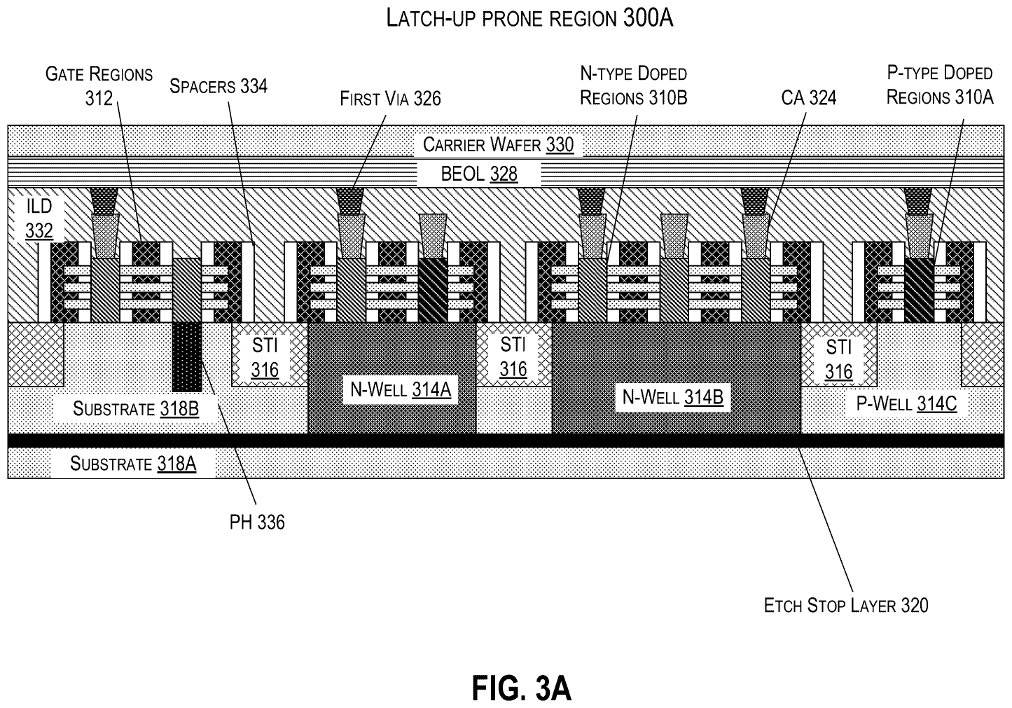

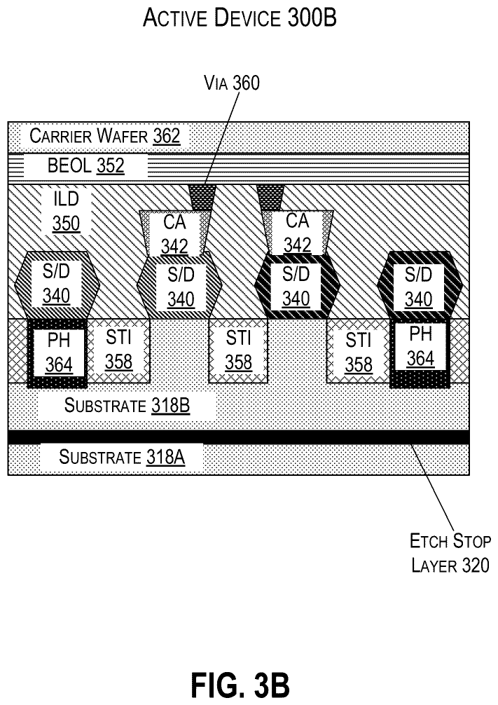

With the foregoing description of an example semiconductor device, it may be helpful to discuss an example process of manufacturing the same. To that end, FIGS. 3-14 illustrate various acts in the manufacture of a semiconductor device, consistent with illustrative embodiments. Figures denoted by A show the acts of fabrication of the semiconductor device in the latch-up prone region, and figures denoted by B illustrate the acts of fabrication of the active device.

Reference now is made to FIGS. 3A-3B, which are simplified cross-section views of a semiconductor device, after the front end of line (FEOL), middle of line (MOL), and BEOL, consistent with an illustrative embodiment. As noted above, the semiconductor device includes a latch-up prone region 300A (which can be in parts of the passive device in the vicinity of the active device) and an active device 300B.

The latch-up prone region 300A can a set of P-type doped regions 310A, a set of N-type doped regions 310B, gate regions 312, a first N-well region 314A, a second N-well region 314B, a P-well region 314C, a first shallow trench isolation, STI 316 between the first N-well region 314A and the second N-well region 314B, a first substrate 318A, a second substrate 318B, an etch stop layer 320, a placeholder, PH 336, frontside contacts, CA 324, a first set of vias 326, a back end of line, BEOL 328, a carrier wafer 330, an interlayer dielectric, ILD 332, and spacers 334.

The active device 300B, which can be a FET, includes source/drain regions, S/D 340, frontside contacts, CA 342, ILD 350, BEOL 352, a STI 358, a second set of vias 360, a carrier wafer 362, PH 364, the first substrate 318A, the second substrate 318B and the etch stop layer 320. It should be noted that, in various embodiments, the latch-up prone region 300A and the active device 300B can share one or more of the BEOL, carrier wafer, first substrate, second substrate, etch stop layer, ILD and STI can be common.

In the illustrative example depicted in FIGS. 3A-3B, the semiconductor device is depicted as being on silicon as the first substrate 318A and the second substrate 318B, while it will be understood that other types as the first substrate 318A and the second substrate 318B may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 318A and the second substrate 318B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 320 is formed over the first substrate 318A. The etch stop layer 320 can be a thin layer of material incorporated into the structure of the semiconductor device to provide a selective barrier against etching processes, preventing further removal of underlying materials during fabrication. The etch stop layer 320 can enable precise control over the etching depth and help define the desired device dimensions. The etch stop layer 320 can further provide a stopping point for the etching process, ensuring that specific layers or regions are not etched beyond a certain point, leading to accurate patterning and control of critical features. The etch stop layer 320 can create a distinct separation between different layers or components within the device structure, and prevent the undesired etching of underlying layers or materials, enabling the creation of complex, multi-layered structures with well-defined interfaces and boundaries. In some embodiments, the etch stop layer 320 acts as a protective barrier for sensitive or delicate materials to shield such materials from aggressive etchants, preventing damage or degradation during subsequent fabrication steps.

In some embodiments, prior to forming the etch stop layer 320, the first substrate 318A is prepared by cleaning and removing any impurities or oxide layers. The etch stop layer 320 is deposited onto the first substrate 318A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 320 can then be selectively etched, stopping at a predetermined depth, while protecting the underlying layers. After the etching process, the remaining photoresist can be removed through stripping techniques. While in some embodiments, SiGe is used to form the etch stop layer 320, in some embodiments, silicon nitride (SiN), silicon oxide (SiO2), or silicon oxynitride (SiON) can be used as the etch stop layer 320.

The spacers 334 can be thin insulating layers or materials placed on the sidewalls of the gate regions 312. The spacers 334 can help control the effective channel length of the latch-up prone region 300A. In an embodiment, the spacers 334 can allow for control over the channel's conductive properties, including resistance and carrier mobility, which can contribute to improved performance of the semiconductor device. The spacers 334 can be a low-k material.

In some embodiments, the spacers 334 can act as insulating layers between the gate regions 312 and the set of N-type doped regions 310B and the set of P-type doped regions 310A. That is, the spacers 334 can help prevent current leakage or short circuits between the gate regions 312 and the set of N-type doped regions 310B and the set of P-type doped regions 310A. Such isolation can help maintain the integrity of the passive device's electrical operation and prevent unintended current flow that could negatively impact the performance of the semiconductor device and reliability.

In further embodiments, the spacers 334 can be utilized to modulate the overlapping capacitance between the gate regions 312 and the set of N-type doped regions 310B and the set of P-type doped regions 310A. Overlapping capacitance can affect the passive device's electrical characteristics, such as threshold voltage and switching behavior. Thus, by adjusting the thickness and material properties of the spacers 334 the overlapping capacitance can be optimized, which can allow for better control and modulation of the passive device's behavior. In several embodiments, the spacers 334 can help mitigate the short-channel effects by physically separating the gate regions 312 from the set of N-type doped regions 310B and the set of P-type doped regions 310A. To that end, the spacers 334 can create a barrier that restricts the extension of the electric field into the channel region. This mitigation can improve the device's performance, reduce power consumption, and enhance overall device reliability.

In an embodiment, the spacers 334 can serve as barriers that prevent the lateral diffusion of dopant atoms from the set of N-type doped regions 310B and the set of P-type doped regions 310A, and into the channel region during the doping process. Such diffusion can alter the channel characteristics and compromise the passive device's performance. By confining the dopant diffusion, the spacers 334 can contribute to maintaining the desired device's characteristics and electrical behavior. In some embodiments, the spacers 334 can be formed over the sidewalls of the gate regions 312. The spacers 334 can be formed by deposition techniques. Alternatively, the spacers 334 can be formed by etching or selectively epitaxially growing the spacers 334 over the sidewalls of the gate regions 312. In various embodiments, the spacers 334 can include SiGe. In some embodiments, the STI 316 can be made of SiN, and the ILD 332 can be made of SiO2.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

In various embodiments, the gate regions 312 serve as control elements that regulate the flow of current through the semiconductor device. The gate regions 312 can be composed of a conductive material. The gate regions 312 can control the flow of electric current between the source and drain regions. In addition to acting as a switch, modulating the gate voltage can enable the gate regions 312 to control the current flowing through the channel region, resulting in amplified output signals.

In an embodiment, the gate regions 312 can enable the implementation of Boolean active operations, such as AND, OR, and NOT, by controlling the flow of current based on the input voltages. In some embodiments, the gate regions 312, along with other active device components, can facilitate the miniaturization and integration of electronic circuits. The ability to control the channel region's conductivity through the gate voltage allows for compact and highly efficient circuit designs.

The gate regions 312 can be formed between the set of N-type doped regions 310B and the set of P-type doped regions 310A, and between the S/D 340. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. In order to fabricate the CA 324 and CA 342, portions of the ILD 332 and 350, the gate regions 312, the STI 316 and STI 358 are removed and filled with a suitable material to form the CA 324 and CA 342.

Generally, the source/drain regions, such as the S/D 340, are salient components that play relevant roles in the semiconductor device's operation. In various embodiments, the S/D 340 is region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

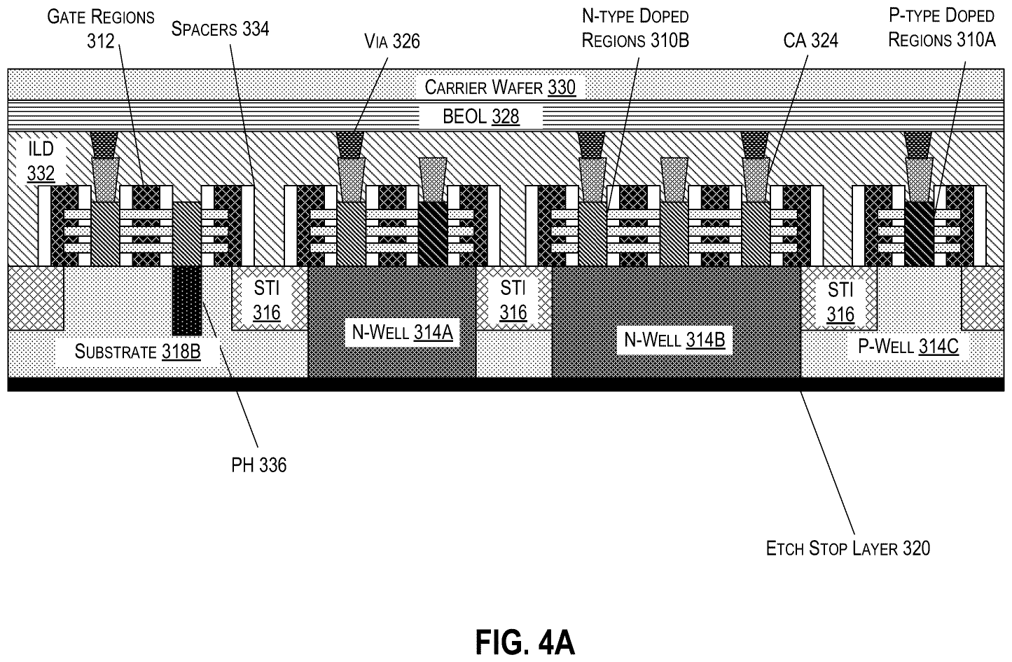

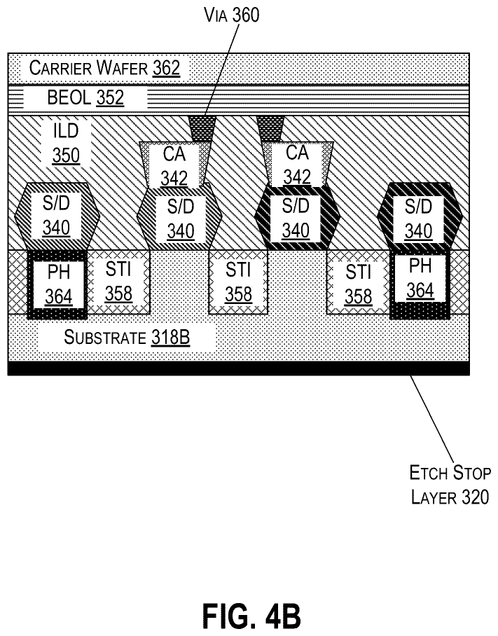

FIGS. 4A-4B illustrate a semiconductor device after the removal of the first substrate, in accordance with some embodiments. In some embodiments, the semiconductor device is flipped and the first substrate is removed. The first substrate removal stops at the etch stop layer 320.

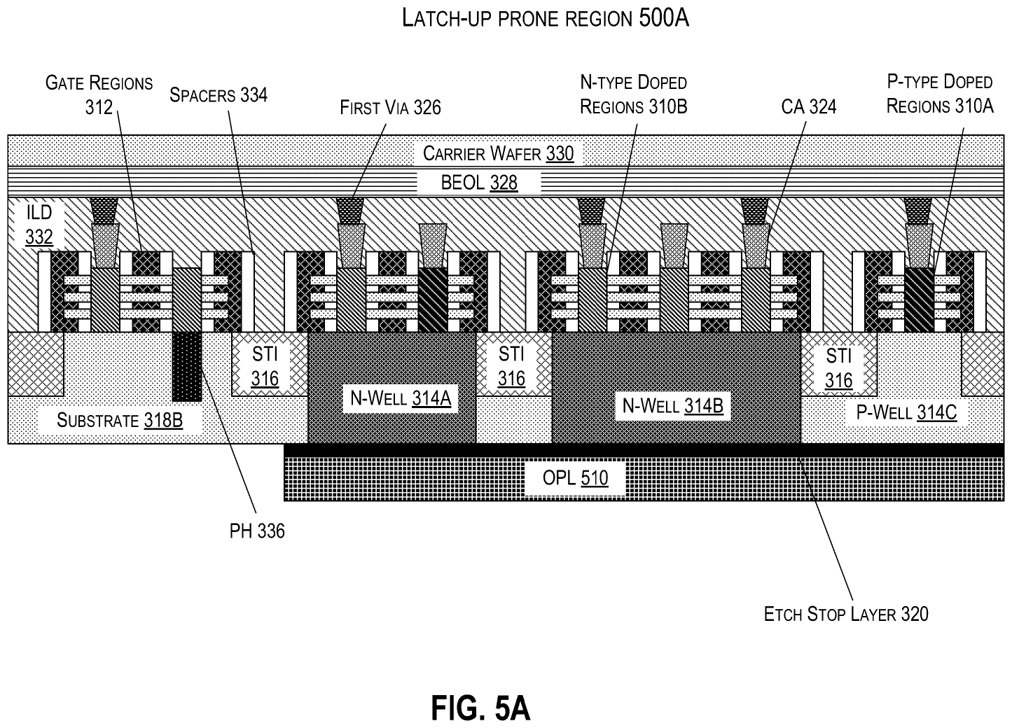

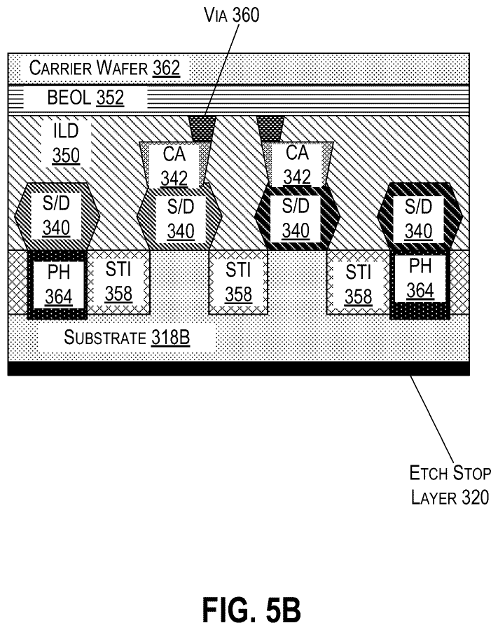

FIGS. 5A-5B illustrate a semiconductor device after the after the patterning of the substrate, in accordance with some embodiments. In some embodiments, an organic planarization layer, OPL 510, is formed over the passive portion of the latch-up prone region 500A. The OPL 510 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 510 can include any organic polymer and a photoactive compound having a molecular structure that can attach to the molecular structure of the organic polymer. In some embodiments, the OPL 510 material is selected to be compatible with an overlying antireflective coating and/or an overlying photoresist. In some embodiments, the OPL 510 can be applied using spin coating technology, although other techniques are within the contemplated scope of the present disclosure. Subsequently, the exposed portions of the etch stop layer are removed.

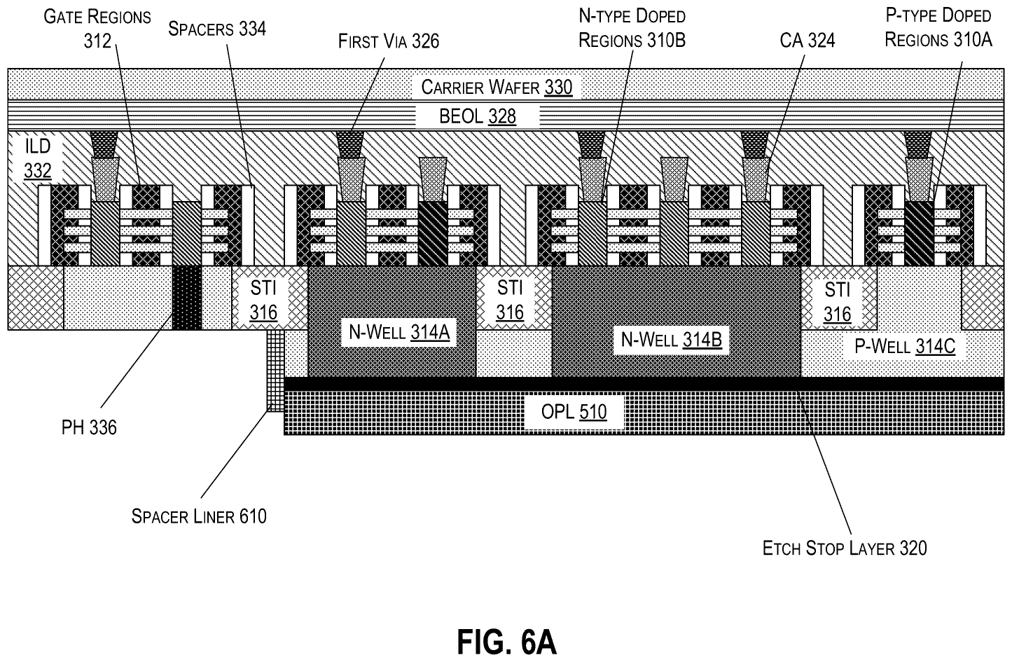

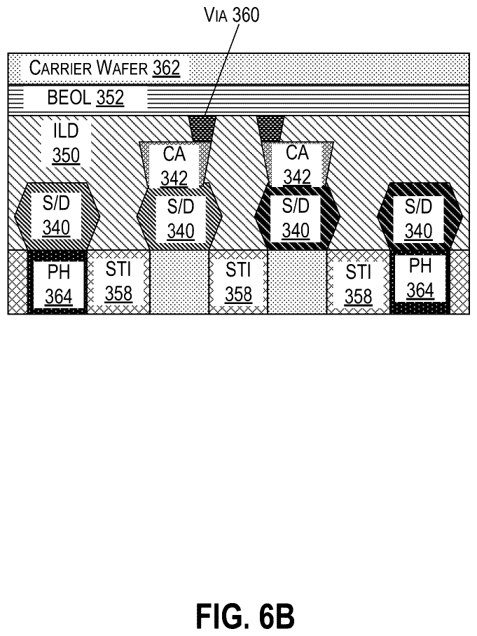

FIGS. 6A-6B illustrate a semiconductor device after the after the formation of the sidewall spacer layer, in accordance with some embodiments. In some embodiments, a spacer layer 610 is formed over the sidewalls of the OPL 510, the etch stop layer 320, and the second substrate 318B. The spacer layer 610 can cover portions of the bottom surface of the STI 316.

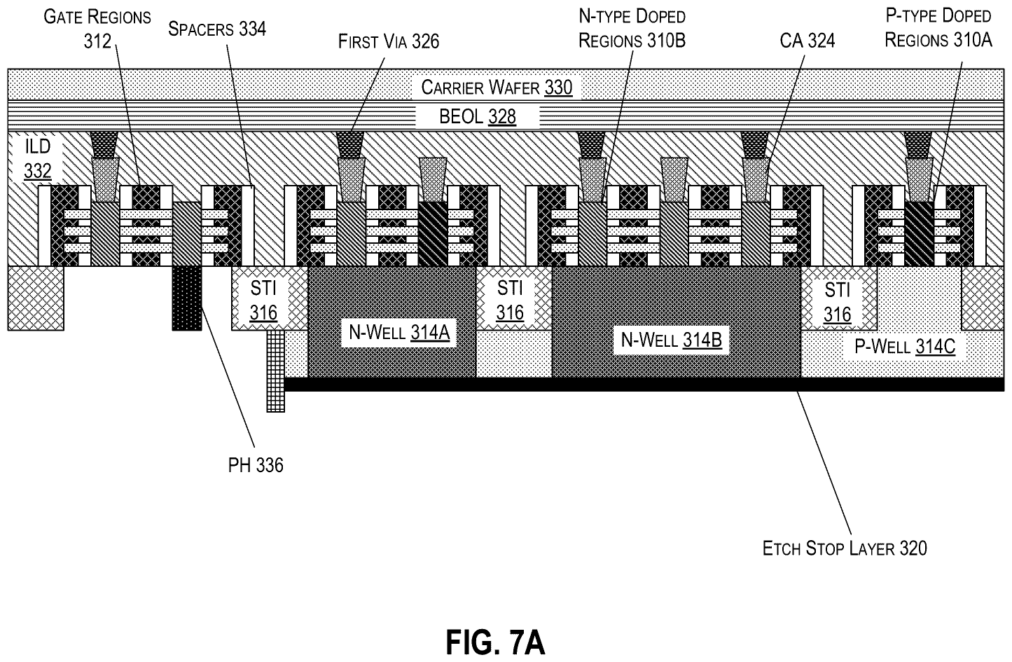

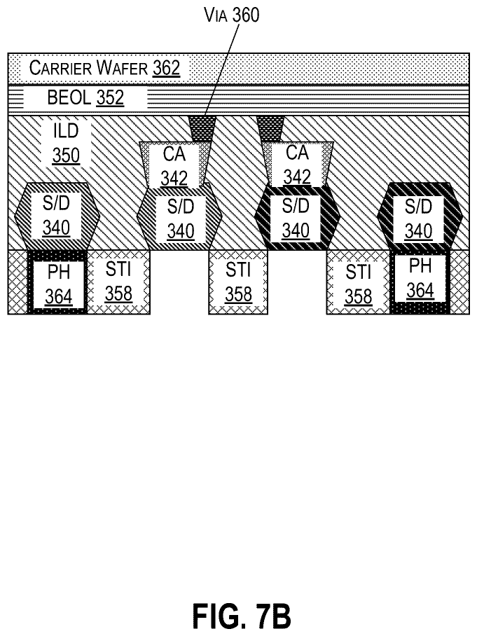

FIGS. 7A-7B illustrate a semiconductor device after the removal of the organic planarization layer, in accordance with some embodiments. In some embodiments, the OPL covering the passive device, and the second substrate are removed.

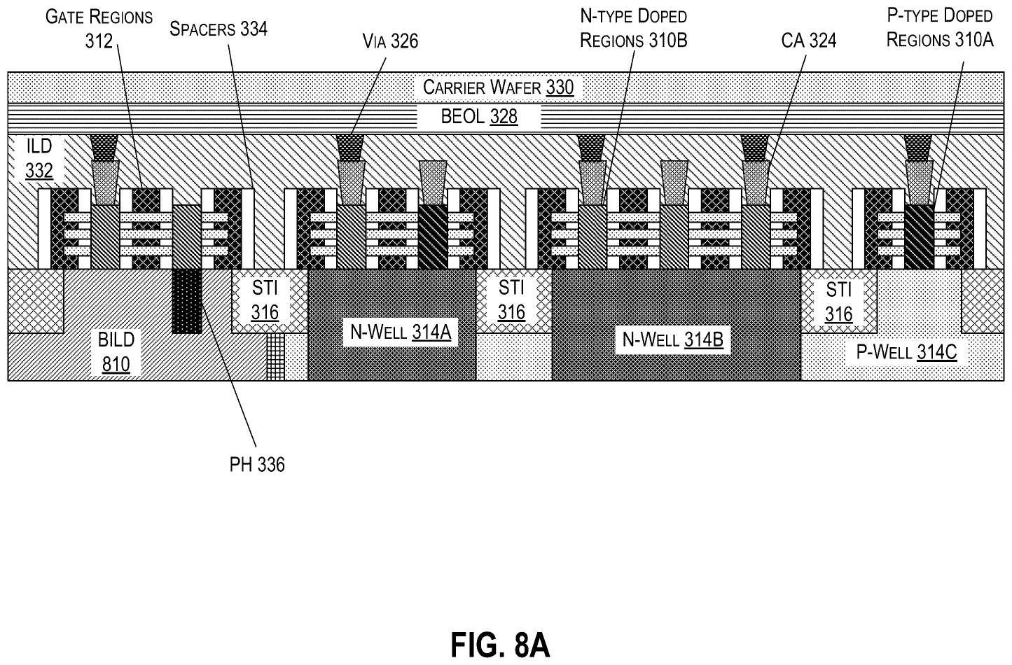

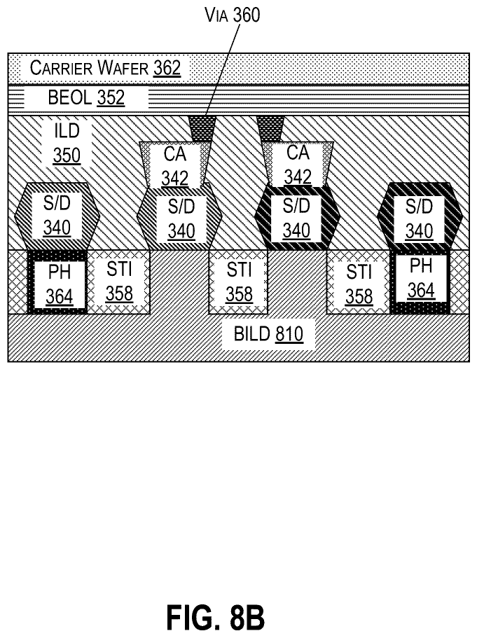

FIGS. 8A-8B illustrate a semiconductor device after the formation of the bottom dielectric layer, in accordance with some embodiments. In some embodiments, the backside dielectric, BILD 810, is formed over the semiconductor device. In various embodiments, the BILD 810 can function as a protective layer, shielding the active regions of the semiconductor device from external contaminants, moisture, and mechanical stress. The BILD 810 can further help prevent physical damage, such as scratches or particle contamination, which could adversely affect semiconductor device performance. Additionally, the BILD 810 can function as a barrier against moisture ingress, which can cause corrosion and degradation of the semiconductor device's components. The BILD 810 can be made of SiO2. In an embodiment, a chemical-mechanical polishing (CMP) process is further processed after the formation of the BILD 810.

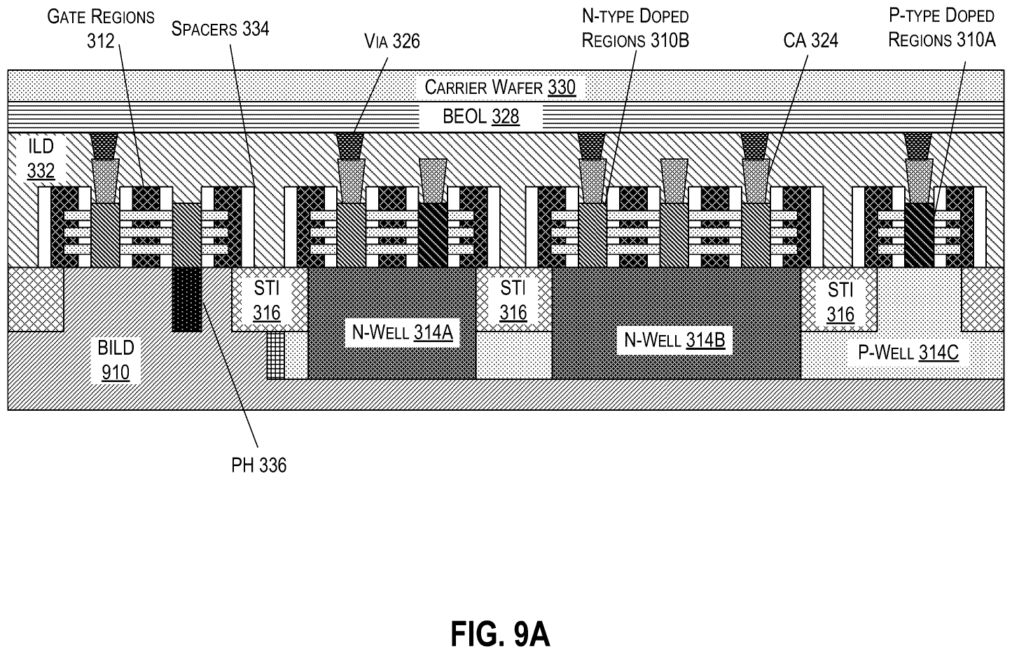

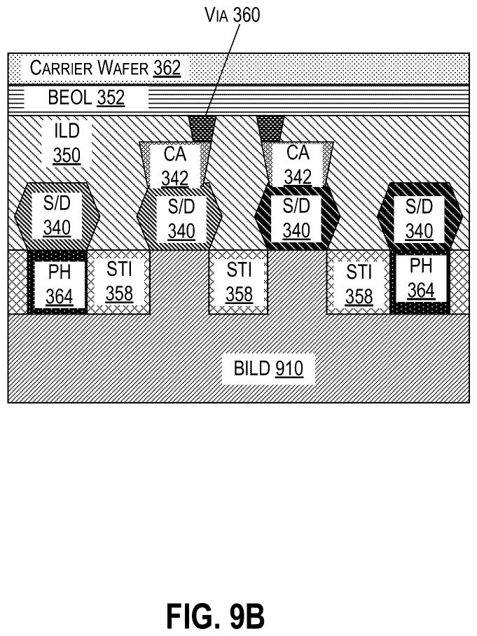

FIGS. 9A-9B illustrate a semiconductor device after the formation of additional bottom dielectric layer, in accordance with some embodiments. In some embodiments, an additional BILD is formed oved the semiconductor device, to cover the entire backside of the semiconductor device. The BILD 910 can include the original BILD 810 formed as described in FIGS. 8A-8B, and the additional BILD formed as described in FIGS. 9A-9B. In some embodiments, BILD 910 can be made of a material which is different from the STI 316.

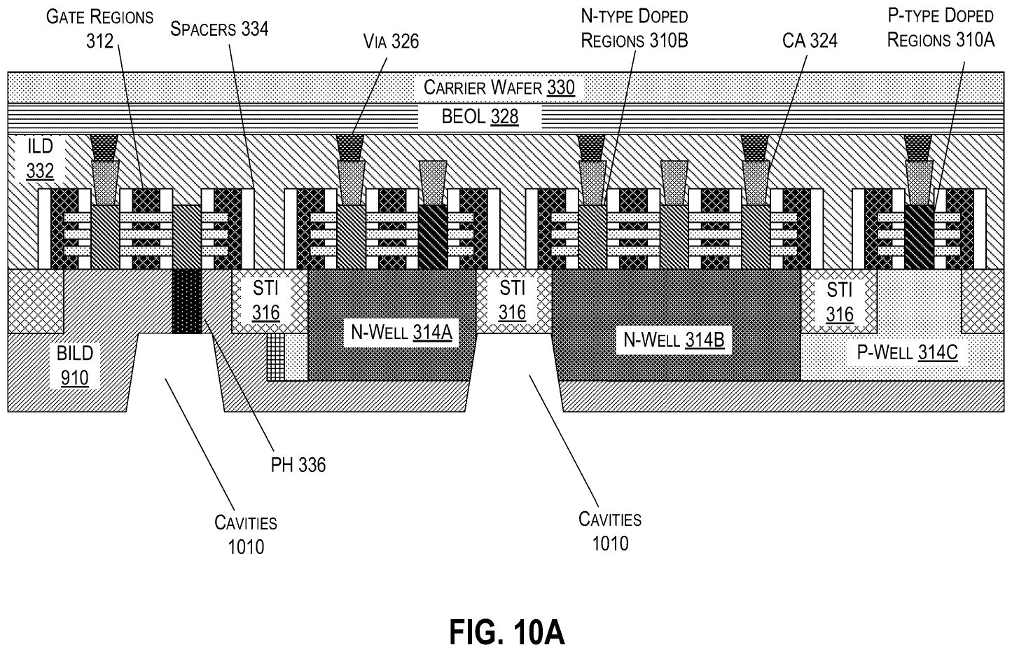

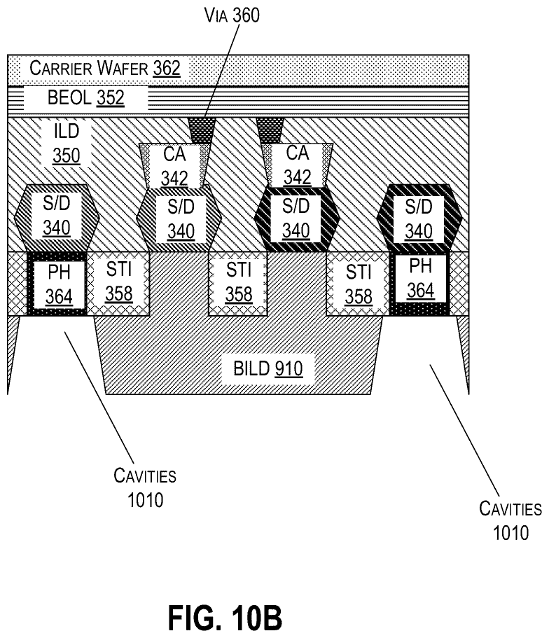

FIGS. 10A-10B illustrate a semiconductor device after the patterning of the backside contact, in accordance with some embodiments. In some embodiments, portions of the BILD 910 below the PH 336 and PH 364 are removed to form cavities 1010.

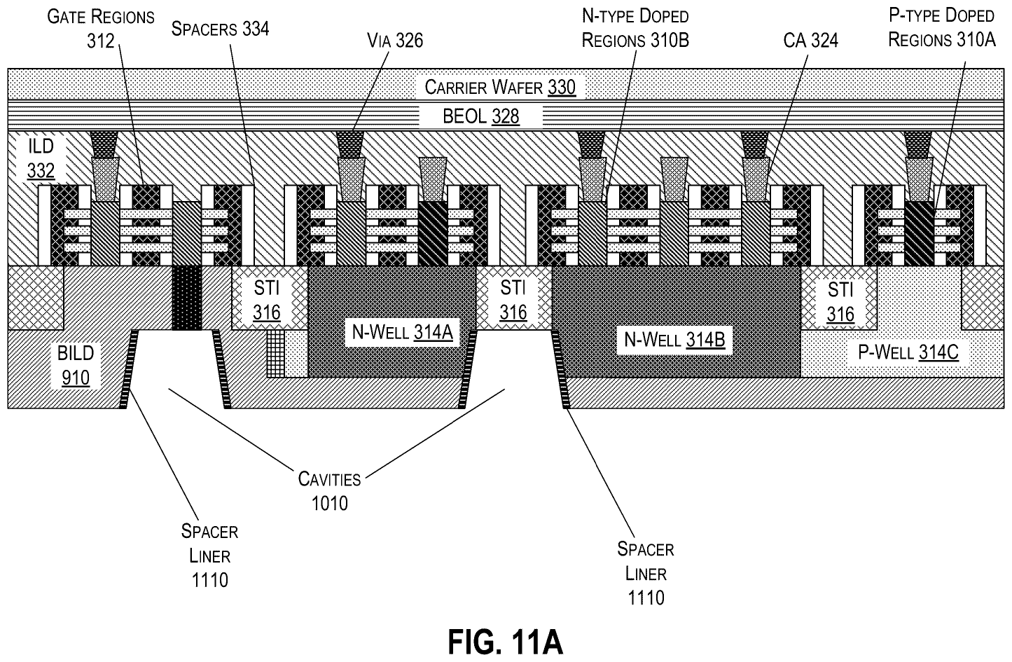

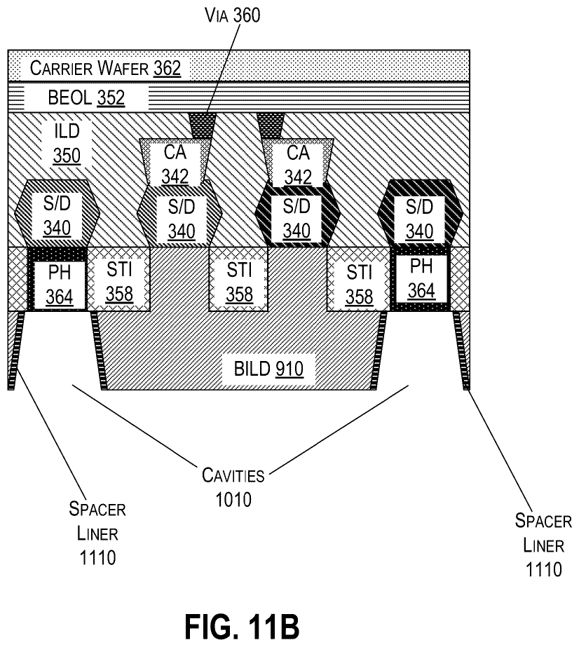

FIGS. 11A-11B illustrate a semiconductor device after the formation of the spacer liner, in accordance with some embodiments. In some embodiments, the spacer liner 1110 is formed over sidewalls of the cavities 1010. The spacer liner 1110 can include a high-k dielectric material.

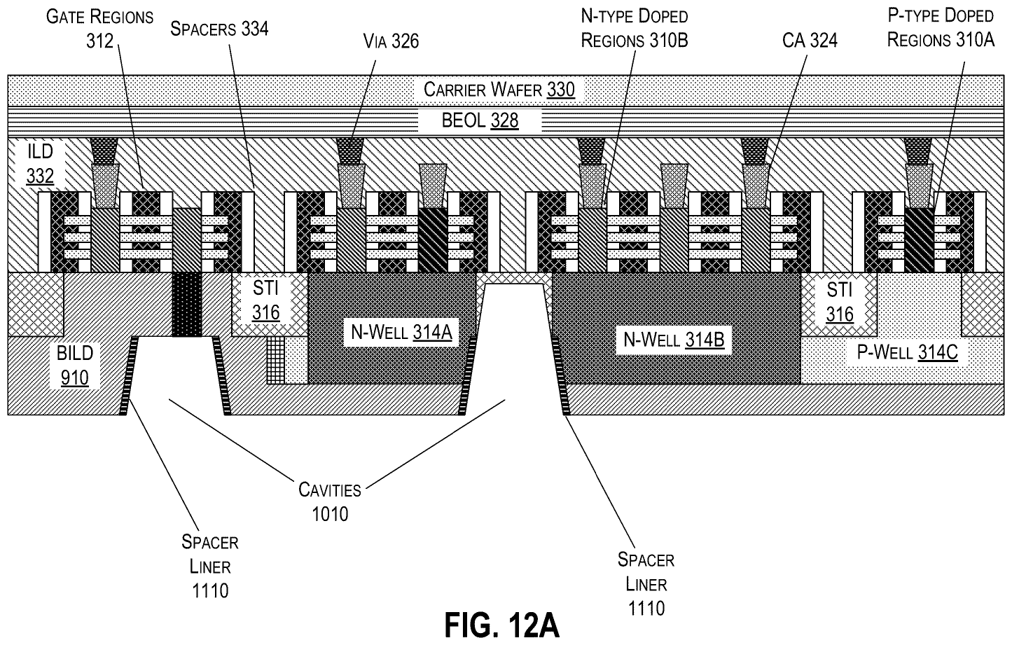

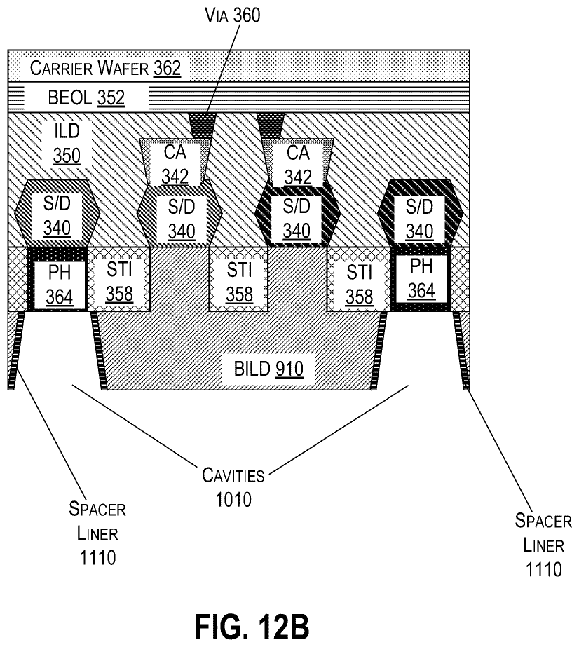

FIGS. 12A-12B illustrate a semiconductor device after the removal of portions of the shallow trench isolation, in accordance with some embodiments. In some embodiments, portions of the STI 316 are removed, e.g., etched, to form a thinner STI 316. Such thinning can increase the capacitance of the decoupling capacitor formed between the backside contact, the N-well regions and the STI.

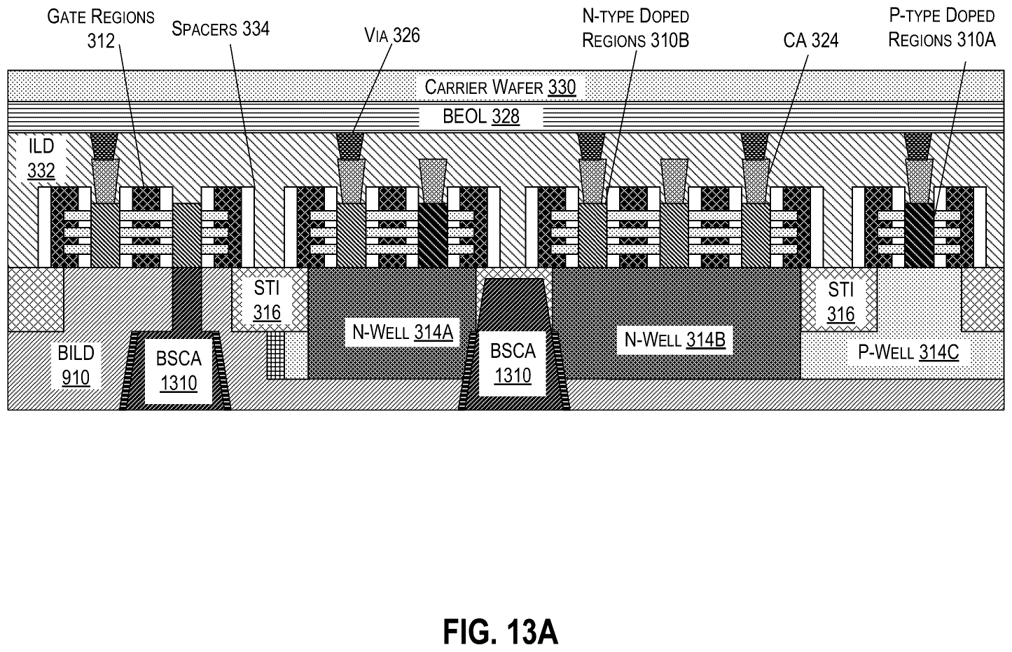

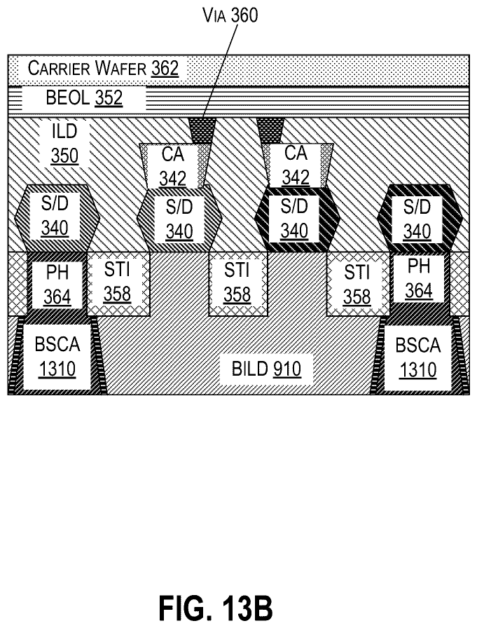

FIGS. 13A-13B illustrate a semiconductor device after the removal of the placeholders, in accordance with some embodiments. In some embodiments, the PH 336 and PH 364 are removed and the backside contacts, BSCA 1310, are formed by filling the recessed areas with a suitable metal. The BSCA 1310 can be surrounded in by the BILD 910, the STI 316 and the spacer liner 1110.

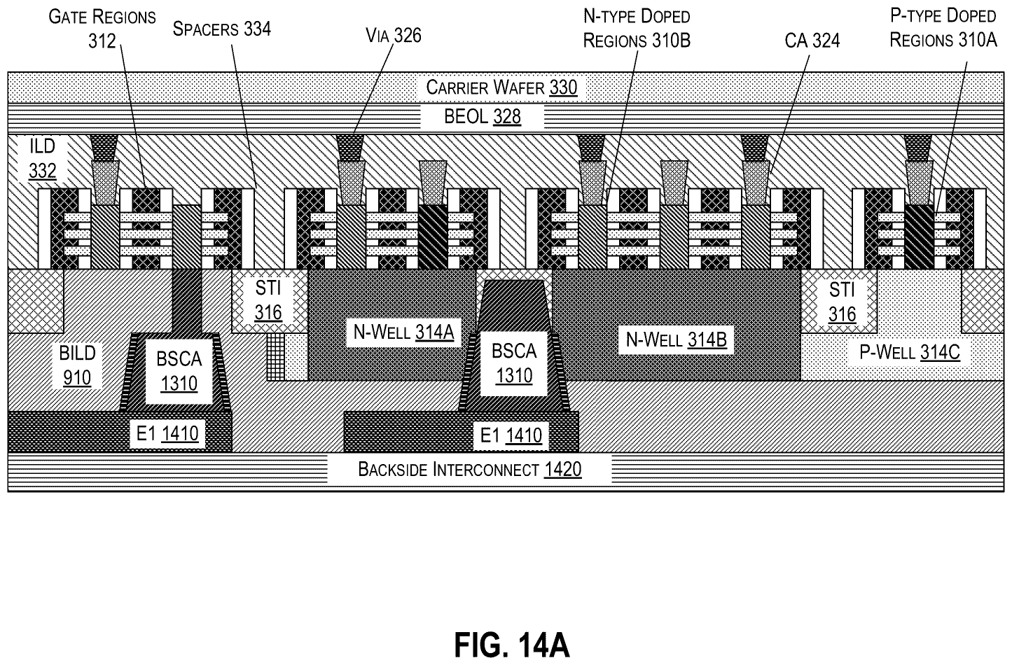

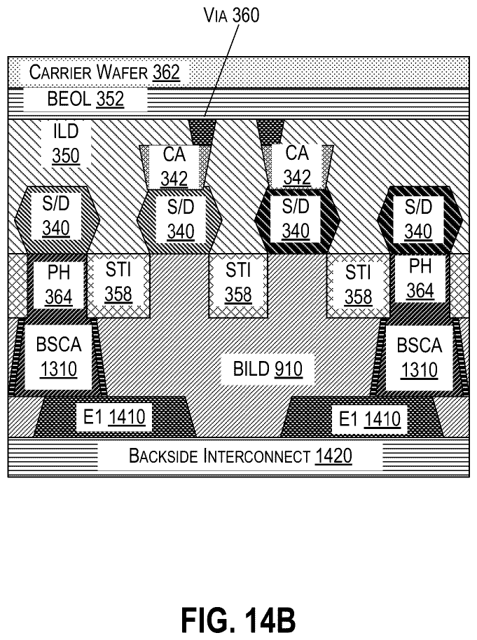

FIGS. 14A-14B illustrate a semiconductor device after the formation of the backside interconnects, in accordance with some embodiments. In some embodiments, a backside metal line, E1 1410, is formed over the BILD 910. A backside interconnect 1420 is formed over the backside of the semiconductor device. As a result, the set of N-type doped regions 310B and the S/D 340 can be connected to the backside interconnect 1420 via the E1 1410.

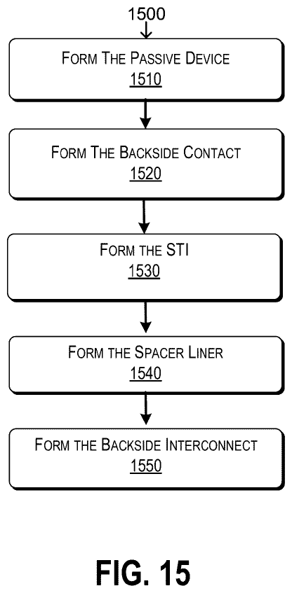

FIG. 15 illustrate a block diagram of a method 1500 for forming the semiconductor device, in accordance with some embodiments. As shown by block 1510, the passive device is formed.

As shown by block 1520, the backside contact is formed.

As shown by block 1530, the STI is formed. The STI can be formed above the backside contact and cover the top surface and the upper half of the sidewalls of the backside contact.

As shown by block 1540, the spacer liner is formed. The spacer liner can cover the lower half of the sidewalls of the backside contact.

As shown by block 1550, the interconnection layer is formed. The interconnection layer can cover the bottom surface of the backside contact.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device, comprising:
a first backside contact;
a shallow trench isolation (STI) above the first backside contact and covering a top surface and an upper half of sidewalls of the first backside contact;
a spacer liner covering a lower half of the sidewalls of the first backside contact; and
an interconnection layer covering a bottom surface of the first backside contact.

2. The semiconductor device of claim 1, wherein the passive device further comprises:
an interlayer dielectric (ILD) above the STI;
a set of P-type doped regions and a set of N-type doped regions on opposite sides of the ILD; and
a first N-well region and a second N-well region below the set of P-type doped regions and the set of N-type doped regions, wherein:
the first N-well region is located on a first side of the spacer liner and the STI, and
the second N-well region is located on a second side of the spacer liner and the STI.

3. The semiconductor device of claim 1, wherein the spacer liner is made of a high-k dielectric material.

4. The semiconductor device of claim 2, wherein the spacer liner and the STI isolate the first N-well region and the second N-well region from contact with the first backside contact.

5. The semiconductor device of claim 1, wherein the passive device is electrically connected to a back end of line (BEOL) through a first via.

6. The semiconductor device of claim 1, further comprising:
an active device, comprising:
source/drain regions;
gate regions; and
a second backside contact.

7. The semiconductor device of claim 6, wherein the active device is electrically connected to a back end of line (BEOL) through a second via.

8. The semiconductor device of claim 6, wherein the active device further comprises alternative layers extended horizontally between two adjacent source/drain regions.

9. The semiconductor device of claim 8, wherein the alternative layers include silicon.

10. A method of fabricating a semiconductor device, the method comprising:
forming a passive device comprising:
forming a first backside contact;
forming a shallow trench isolation (STI) above the first backside contact and covering a top surface and an upper half of sidewalls of the first backside contact;
forming a spacer liner covering a lower half of the sidewalls of the first backside contact; and
forming an interconnection layer covering a bottom surface of the first backside contact.

11. The method of claim 10, further comprising:
forming an interlayer dielectric (ILD) above the STI;
forming a set of P-type doped regions and a set of N-type doped regions on opposite sides of the ILD;
forming a first N-well region below the set of P-type doped regions and the set of N-type doped regions on a first side of the spacer liner and the STI; and
forming a second N-well region below the set of P-type doped regions and the set of N-type doped regions on a second side of the spacer liner and the STI.

12. The method of claim 11, further comprising isolating the first N-well region and the second N-well region from contact with the first backside contact via the spacer liner and the STI.

13. The method of claim 10, further comprising establishing an electrical connection between the passive device and a back end of line (BEOL) through a first via.

14. The method of claim 10, further comprising:
forming an active device, comprising:
forming source/drain regions;
forming gate regions between the source/drain regions; and
forming a second backside contact below one of the source/drain regions.

15. The method of claim 14, further comprising forming alternative layers extended horizontally between two adjacent source/drain regions.

16. The method of claim 15, further comprising establishing an electrical connection between the active device and a back end of line (BEOL) through a second via.

17. A semiconductor device, comprising:
a backside contact;
a spacer liner covering lower half of sidewalls of the backside contact; and
an N-well region connected to the spacer liner so that the spacer liner isolates the N-well region from contact with the backside contact, wherein:
the spacer liner is made of a high-k dielectric material,
the N-well region is electrically connected to a voltage source/drain supply, and
the backside contact is connected to a voltage drain/source supply or to a ground voltage.

18. The semiconductor device of claim 17, further comprising:
a shallow trench isolation (STI) above the backside contact and covering a top surface and
an upper half of sidewalls of the backside contact; and
an interconnection layer covering a bottom surface of the backside contact.

19. The semiconductor device of claim 18, further comprising:
an interlayer dielectric (ILD) above the STI;
a set of P-type doped regions and a set of N-type doped regions on opposite sides of the ILD; and
a first N-well region and a second N-well region below the set of P-type doped regions and the set of N-type doped regions, wherein:
the first N-well region is located on a first side of the spacer liner, and
the STI, and the second N-well region.

20. The semiconductor device of claim 19, wherein the spacer liner isolates the first N-well region and the second N-well region from contact with the backside contact.
